(19) United States
(12) Patent Application Publication
(10) Pub. No.: US 2023/0232649 A1
(43) Pub. Date: Jul. 20, 2023

(54) DISPLAY DEVICE

(71) Applicant: Samsung Display Co., Ltd., Yongin-si (KR)

(72) Inventors: HYEONGPIL KIM, Osan-si (KR); BEOMJOON KIM, Seoul (KR); ILHA SONG, Asan-si (KR); DAEWOONG LEE, Seoul (KR); BORA LEE, Hwaseong-si (KR); ILLHUN CHO, Seoul (KR)

(21) Appl. No.: 17/979,551

(22) Filed: Nov. 2, 2022

(30) Foreign Application Priority Data
Jan. 17, 2022 (KR) 10-2022-0006515

(51) Int. Cl. H01L 51/50; H01L 27/32; H01L 51/52

(52) U.S. Cl. CPC H01L 51/504; H01L 51/5092; H01L 27/3246; H01L 51/5218; H01L 51/5072; H01L 51/5056

(57) ABSTRACT

A display device including a base layer including a first pixel area configured to emit a first light therefrom and a second pixel area configured to emit a second light therefrom, a first electrode on the base layer, a second electrode on the first electrode and facing the first electrode, first light emitting stacks between the first and second electrodes and in the first pixel area, a first charge generation layer between the first light emitting stacks, second light emitting stacks between the first and second electrodes and in the second pixel area, and a second charge generation layer between the second light emitting stacks. The first charge generation layer includes a first metal, the second charge generation layer includes a second metal different from the first metal, and the second metal has a work function equal to or greater than 1.7 eV and equal to or smaller than 3.2 eV.

### CROSS-REFERENCE TO RELATED APPLICATION

This application claims priority to and the benefit of Korean Patent Application No. 10-2022-0006515, filed on Jan. 17, 2022, the entire content of which is incorporated by reference herein.

### BACKGROUND

### 1. Field

The present disclosure relates to a display device.

### 2. Description of the Related Art

Organic light emitting elements may have a fast response speed, may be driven at low voltage, and are self-emissive. Accordingly, organic light emitting display devices employing organic light emitting elements do not require a separate light source and may have various desired features such as being lightweight, thin thickness, high brightness, and no viewing-angle dependence.

An organic light emitting element is a display element that includes an anode electrode, a cathode electrode, and a light emitting layer formed of an organic material and disposed between the anode electrode and the cathode electrode. Holes provided from the anode electrode are recombined with electrons provided from the cathode electrode in the light emitting layer to generate excitons, and the excitons emit light corresponding to energy between the holes and the electrons.

A tandem organic light emitting element has a structure in which two or more stacks each including a hole transport layer/a light emitting layer/an electron transport layer are disposed between an anode electrode and a cathode electrode, and a charge generation layer is present between the stacks to assist generation and movement of electrons.

### SUMMARY

Aspects of one or more embodiments of the present disclosure are directed towards a display device in which light emitting elements are designed to have characteristics matching a light emitting range to improve display efficiency.

Aspects of one or more embodiments of the present disclosure are directed towards a display device capable of preventing or reducing a driving voltage from rising and having improved display efficiency.

Additional aspects will be set forth in part in the description that follows and, in part, will be apparent from the description, or may be learned by practice of the presented embodiments of the disclosure.

Embodiments of the present disclosure provide a display device including a base layer including a first pixel area configured to emit a first light therefrom and a second pixel area configured to emit a second light, different from the first light, therefrom, a first electrode on the base layer, a second electrode on the first electrode and facing the first electrode, a plurality of first light emitting stacks between the first electrode and the second electrode and in the first pixel area, a first charge generation layer between the first light emitting stacks, a plurality of second light emitting stacks between the first electrode and the second electrode and in the second pixel area, and a second charge generation layer between the second light emitting stacks. The first charge generation layer includes a first metal, the second charge generation layer includes a second metal different from the first metal, and the second metal has a work function equal to or greater than about 1.7 eV and equal to or smaller than about 3.2 eV.

In one more embodiments, the first metal may include ytterbium (Yb).

In one more embodiments, the second metal may include at least one of lithium (Li), potassium (K), rubidium (Rb), cesium (Cs), barium (Ba), europium (Eu), sodium (Na), strontium (Sr), samarium (Sm), calcium (Ca), terbium (Tb), or cerium (Ce).

In one more embodiments, the display device may further include an electron injection doping layer on the first electrode and under the first light emitting stacks and the second light emitting stacks and a hole injection doping layer on the first light emitting stacks and the second light emitting stacks and under the second electrode.

In one more embodiments, the electron injection doping layer may include a third metal having a work function equal to or greater than about 1.7 eV and equal to or smaller than about 3.2 eV, and the hole injection doping layer may include an organic material with a highest occupied molecular orbital (HOMO) level equal to or greater than about −6.0 eV and equal to or smaller than about −4.0 eV.

In one more embodiments, each of the electron injection doping layer and the hole injection doping layer may entirely overlap the first pixel area and the second pixel area.

In one more embodiments, at least a portion of the first light emitting stacks may include a first light emitting layer configured to emit the first light, and at least a portion of the second light emitting stacks may include a second light emitting layer configured to emit the second light.

In one more embodiments, the second charge generation layer may not overlap the first pixel area.

In one more embodiments, the display device may further include a pixel definition layer on the base layer and provided with a plurality of openings defined therethrough to respectively correspond to the first pixel area and the second pixel area and a bank on the pixel definition layer and between (e.g., interposed between) at least a portion of the first light emitting stacks and at least a portion of the second light emitting stacks.

In one more embodiments, the first electrode may be a reflective electrode, the second electrode may be a transflective electrode or a transmissive electrode, and the first and second lights may be configured to be emitted in a direction from the first electrode to the second direction.

In one more embodiments, the display device may further include a circuit layer on the base layer and including a transistor electrically connected to the first electrode.

In one more embodiments, the transistor may be an NMOS transistor.

In one more embodiments, each of the first light emitting stacks may include a first electron transport layer adjacent to the first electrode, a first light emitting layer on the first electron transport layer, and a first hole transport layer spaced apart from the first electron transport layer with the first light emitting layer interposed therebetween and adjacent to the second electrode, and each of the second light emitting stacks may include a second electron transport layer adjacent to the first electrode, a second light emitting layer on the second electron transport layer, and a second hole transport layer spaced apart from the second electron transport layer with the second light emitting layer interposed therebetween and adjacent to the second electrode.

In one more embodiments, the base layer may include a third pixel area adjacent to the first pixel area and the second pixel area, and the first light emitting stacks may overlap the third pixel area.

In one more embodiments, the base layer may include a non-pixel area defined therein to be around each of the first pixel area, the second pixel area, and the third pixel area, and one or more of the first light emitting stacks may overlap the non-pixel area.

In one more embodiments, the second metal may have an electrical conductivity higher than an electrical conductivity of the first metal.

In one more embodiments, the first charge generation layer may include an n-type first charge generation layer (e.g., a first N-charge generation layer), the second charge generation layer may include an n-type second charge generation layer (e.g., a second N-charge generation layer), and the n-type first charge generation layer may include the first metal, and the n-type second charge generation layer may include the second metal.

One or more embodiments of the present disclosure provide a display device including a base layer including a first pixel area configured to emit a first light therefrom and a second pixel area configured to emit a second light, different from the first light, therefrom, a first electrode on the base layer, a second electrode on the first electrode and facing the first electrode, a plurality of first light emitting stacks between the first electrode and the second electrode and in the first pixel area, a first charge generation layer between the first light emitting stacks, a plurality of second light emitting stacks between the first electrode and the second electrode and in the second pixel area, and a second charge generation layer between the second light emitting stacks. The first charge generation layer includes ytterbium (Yb), and the second charge generation layer includes at least one of lithium (Li), potassium (K), rubidium (Rb), cesium (Cs), barium (Ba), europium (Eu), sodium (Na), strontium (Sr), samarium (Sm), calcium (Ca), terbium (Tb), or cerium (Ce).

In one more embodiments, the first charge generation layer may not overlap the second pixel area, and the second charge generation layer may not overlap the first pixel area.

One or more embodiments of the present disclosure provide a display device including a base layer including a first pixel area configured to emit a first light therefrom and a second pixel area configured to emit a second light, different from the first light, therefrom, a first electrode on the base layer, a second electrode on the first electrode and facing the first electrode, an electron injection doping layer on the first electrode, a plurality of first light emitting stacks on the electron injection doping layer and in the first pixel area, a first charge generation layer between the first light emitting stacks, a plurality of second light emitting stacks on the electron injection doping layer and in the second pixel area, a second charge generation layer between the second light emitting stacks, and a hole injection doping layer on the plurality of first light emitting stacks and the plurality of second light emitting stacks and under the second electrode. The first charge generation layer includes a first metal, and the second charge generation layer includes a second metal different from the first metal.

According to the above, materials for the charge generation layers are selected to allow the light emitting elements emitting different lights from each other to have different device characteristics, such as driving voltages, and thus, the light emitting elements are designed to have device characteristics matching their own light emitting range. Accordingly, the display device including the light emitting elements has improved display efficiency.

### BRIEF DESCRIPTION OF THE DRAWINGS

The above and other features, aspects and/or principles of the present disclosure will become readily apparent by reference to the following detailed description when considered in conjunction with the accompanying drawings, wherein:

FIG. 1 is a plan view of a display device according to one or more embodiments of the present disclosure;

FIG. 2A is a cross-sectional view of the display device taken along the line I-I′ of FIG. 1, according to one or more embodiments of the present disclosure;

FIG. 2B is a cross-sectional view of the display device taken along the line II-II′ of FIG. 1, according to one or more embodiments of the present disclosure;

FIGS. 2C-2F are plan views of components of a display device according to one or more embodiments of the present disclosure; and

FIG. 3A-3C are cross-sectional views of light emitting elements according to one or more embodiments of the present disclosure.

### DETAILED DESCRIPTION

Hereinafter, embodiments of the present disclosure will be described with reference to accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present. In addition, it will also be understood that when an element or layer is referred to as being “between” two elements or layers, it can be the only element or layer between the two elements or layers, or one or more intervening elements or layers may also be present.

Like numerals refer to like elements throughout, and duplicative descriptions thereof may not be provided. In the drawings, the thickness, ratio, and dimension of components are exaggerated for effective description of the technical content. As utilized herein, the term “and/or” may include any and all combinations of one or more of the associated listed items. Expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

It will be understood that, although the terms first, second, etc. may be utilized herein to describe various elements, these elements should not be limited by these terms. These terms are only utilized to distinguish one element from another element. Thus, a first element discussed below could be termed a second element without departing from the teachings of the present disclosure. As utilized herein, the singular forms, “a”, “an” and “the” are intended to include the plural forms as well, unless the context clearly indicates otherwise.

Spatially relative terms, such as “beneath”, “below”, “lower”, “above”, “upper” and the like, may be utilized herein for ease of description to describe one element or feature's relationship to another elements or features as shown in the drawings. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be further understood that the terms “include,” “including”, “comprise,” and “comprising” when utilized in this specification, specify the presence of stated features, integers, steps, operations, elements, and/or components, but do not preclude the presence or addition of one or more other features, integers, steps, operations, elements, components, and/or groups thereof.

In the present disclosure, when an element is referred to as being “directly disposed” to another element, there are no intervening elements present between a layer, film region, or substrate and another layer, film, region, or substrate. For example, the term “directly disposed” may mean that two layers or two members are disposed without employing additional adhesive therebetween.

As used herein, the term “substantially,” “about,” and similar terms are used as terms of approximation and not as terms of degree, and are intended to account for the inherent deviations in measured or calculated values that would be recognized by those of ordinary skill in the art. “Substantially” or “about” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” or “about” may mean within one or more standard deviations, or within ±30%, 20%, 10%, 5% of the stated value. Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms including technical and scientific terms utilized herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

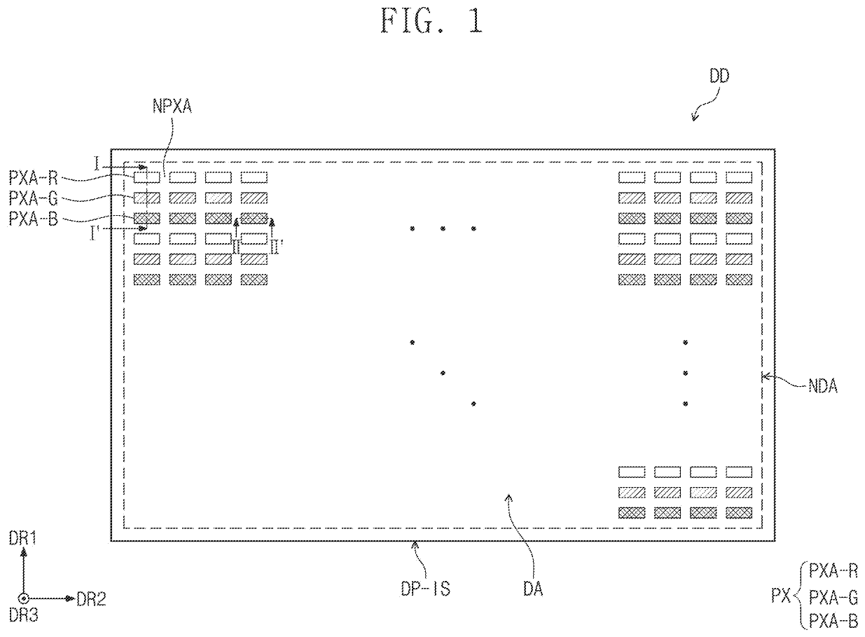

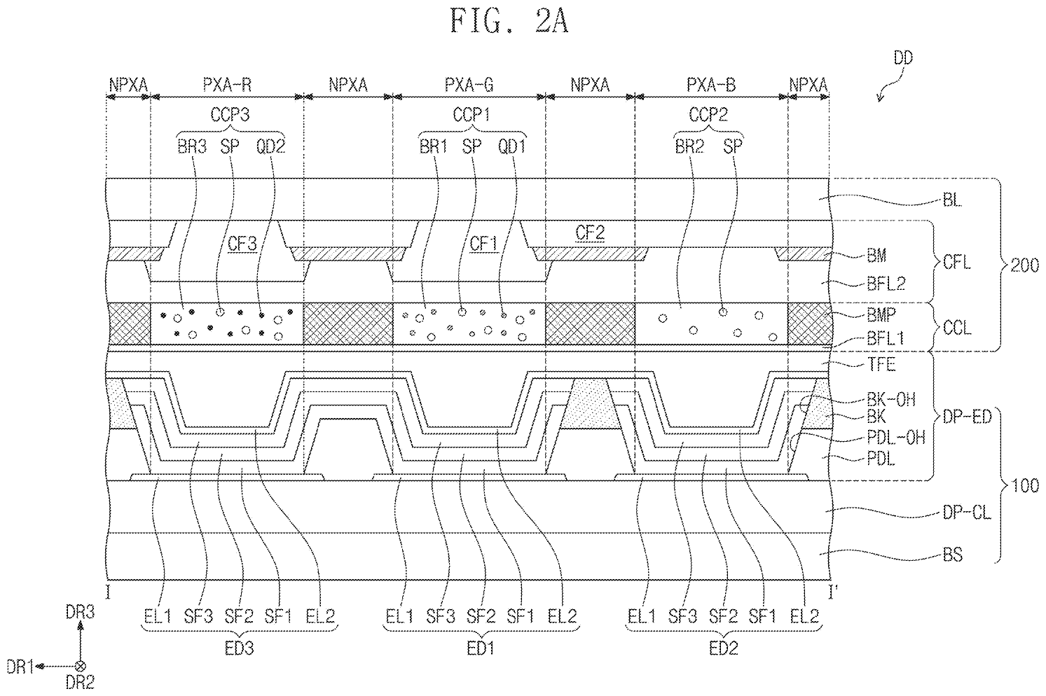

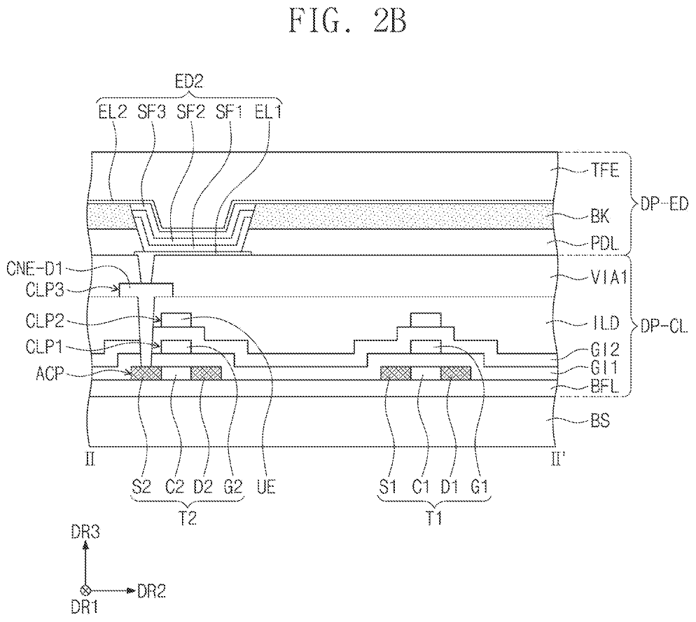

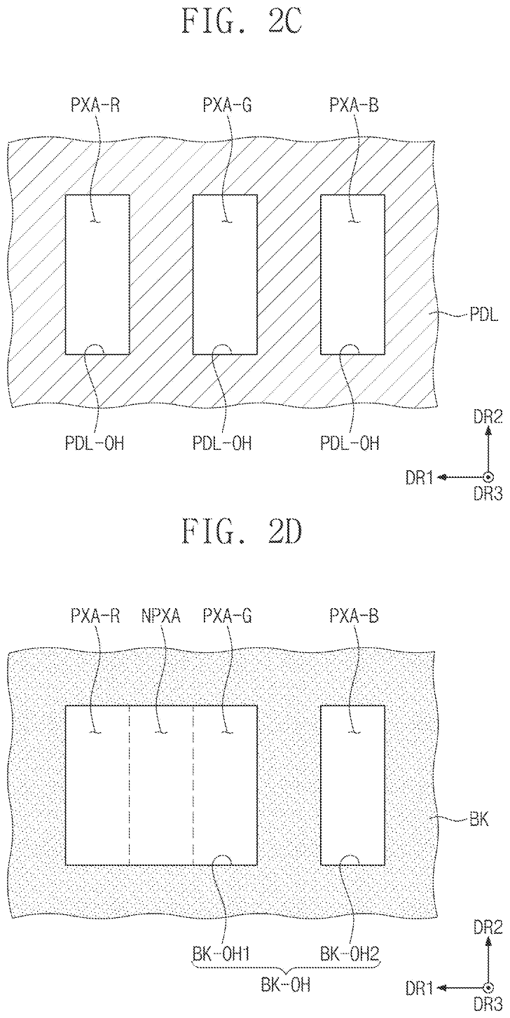

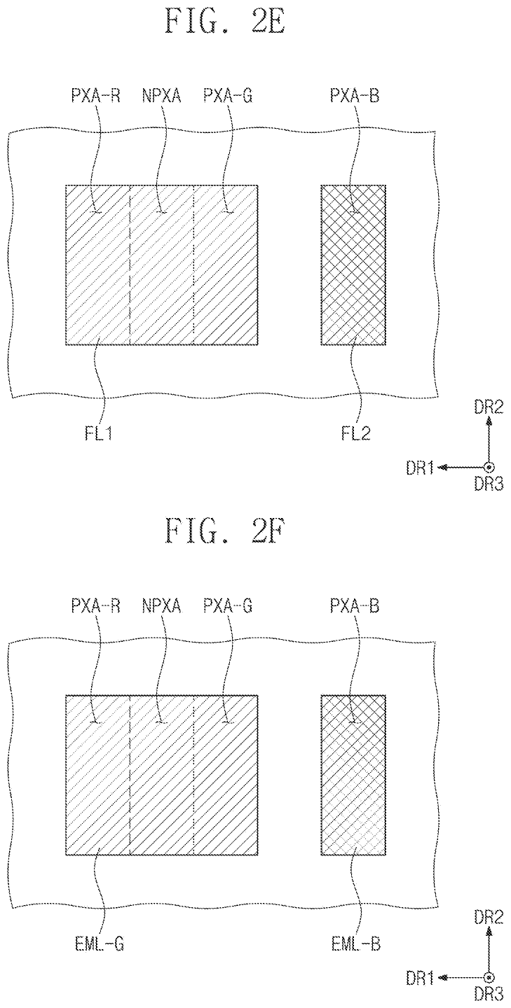

FIG. 1 is a plan view of a display device DD according to one or more embodiments of the present disclosure. FIGS. 2A and 2B are cross-sectional views of the display device DD according to one or more embodiments of the present disclosure. FIG. 2A is a cross-sectional view of the display device DD taken along the line I-I′ of FIG. 1. FIG. 2B is a cross-sectional view of the display device DD taken along the line II-II′ of FIG. 1.

Referring to FIG. 1, the display device DD may display an image through a display surface DP-IS. The display surface DP-IS may be substantially parallel to a plane defined by a first direction DR1 and a second direction DR2. The display surface DP-IS may include a display area DA and a non-display area NDA. A pixel PX may be disposed in the display area DA. The non-display area NDA may be defined along an edge of the display surface DP-IS. The non-display area NDA may be adjacent to the display area DA. The non-display area NDA may be around (e.g., surround) the display area DA.

A third direction DR3 may indicate a normal line direction of the display surface DP-IS, i.e., a thickness direction of the display device DD. Front (or upper) and rear (or lower) surfaces of each layer or each unit described hereinafter may be distinguished from each other by the third direction DR3. The front surface and the rear surface may be opposite to each other. In one or more embodiments, the first, second, and third directions DR1, DR2, and DR3 described in the present embodiments are relative to each other and may be changed to other directions. According to one or more embodiments, the display device DD may include the display surface DP-IS that is a flat type or kind, however, the display surface DP-IS should not be limited to the flat type or kind. The display device DD may include a curved display surface or a three-dimensional display surface. The three-dimensional display surface may include plural (e.g., multiple) display areas that face different directions from each other.

Referring to FIG. 2A, the display device DD may include a lower display substrate 100 and an upper display substrate 200 disposed on the lower display substrate 100. In one or more embodiments, a filling layer may be filled between the lower display substrate 100 and the upper display substrate 200. Hereinafter, the lower display substrate 100 will be described as a display panel 100.

The display panel 100 may be one of a liquid crystal display panel, an electrophoretic display panel, a microelectromechanical system (MEMS) display panel, an electrowetting display panel, an organic light emitting display panel, a micro-LED display panel, a quantum dot display panel, or a quantum rod display panel; however, the present disclosure is not particularly limited thereto.

The display panel 100 may include a base layer BS, a circuit layer DP-CL, and a display element layer DP-ED. The circuit layer DP-CL and the display element layer DP-ED may be disposed on the base layer BS. The display element layer DP-ED may include a pixel definition layer PDL and light emitting elements ED1, ED2, and ED3 disposed to overlap pixel openings PDL-OH defined through the pixel definition layer PDL.

The pixel definition layer PDL may separate (e.g., define) pixel areas PXA-G, PXA-B, and PXA-R from each other. A non-pixel area NPXA may be an area between the pixel areas PXA-G, PXA-B, and PXA-R adjacent to each other and may correspond to the pixel definition layer PDL. The non-pixel area NPXA may be defined to be around (e.g., surround) each of the pixel areas PXA-G, PXA-B, and PXA-R.

The light emitting elements ED1, ED2, and ED3 may be disposed to overlap the pixel areas PXA-G, PXA-B, and PXA-R, respectively. The pixel areas PXA-G, PXA-B, and PXA-R may be areas from which lights generated by the light emitting elements ED1, ED2, and ED3 are emitted, respectively.

As an example, the pixel areas PXA-G, PXA-B, and PXA-R may include a first pixel area PXA-G, a second pixel area PXA-B, and a third pixel area PXA-R, which are disposed spaced apart from each other. The light emitting elements ED1, ED2, and ED3 may include a first light emitting element ED1 overlapping the first pixel area PXA-G, a second light emitting element ED2 overlapping the second pixel area PXA-B, and a third light emitting element ED3 overlapping the third pixel area PXA-R.

The first pixel area PXA-G may be a green pixel area, the second pixel area PXA-B may be a blue pixel area, and the third pixel area PXA-R may be a red pixel area.

In the display device DD, at least some (e.g., one) of the first light emitting element ED1, the second light emitting element ED2, or the third light emitting element ED3 may be to emit lights of different wavelength ranges from each other. As an example, the first light emitting element ED1 may be to emit a green light, and the second light emitting element ED2 may be to emit a blue light. According to one or more embodiments, the first light emitting element ED1 may be to emit a green light, and the second light emitting element ED2 may be to emit a blue light, and the third light emitting element ED3 may be to emit a green light. According to one or more embodiments, the first light emitting element ED1 may be to emit a green light, and the second light emitting element ED2 may be to emit a blue light, and the third light emitting element ED3 may be to emit a red light. However, the present disclosure should not be limited thereto or thereby. According to one or more embodiments, the first, second, and third light emitting elements ED1, ED2, and ED3 may be to emit lights of the same wavelength range, or at least one of the first, second, and/or third light emitting elements ED1, ED2, and ED3 may be to emit a light of different wavelength range from those of the others.

The pixel areas PXA-G, PXA-B, and PXA-R of the display device DD may be arranged in a stripe form. Referring to FIG. 1, each of a plurality of first pixel areas PXA-G, a plurality of second pixel areas PXA-B, and a plurality of third pixel areas PXA-R may be arranged in the second direction DR2. In one or more embodiments, the second pixel area PXA-B, the first pixel area PXA-G, and the third pixel area PXA-R may be repeatedly arranged along the first direction DR1 in order of the second, first, and third pixel area PXA-B, PXA-G, and PXA-R.

In FIGS. 1 and 2A, the pixel areas PXA-G, PXA-B, and PXA-R have similar sizes, however, the present disclosure should not be limited thereto or thereby. According to one or more embodiments, the sizes of the pixel areas PXA-G, PXA-B, and PXA-R may be different from each other according to wavelength ranges of lights emitted therefrom. In one or more embodiments, the sizes of the pixel areas PXA-G, PXA-B, and PXA-R may indicate sizes when viewed in a plane defined by the first direction DR1 and the second direction DR2 (e.g., in a plan view).

In one or more embodiments, the arrangement of the pixel areas PXA-G, PXA-B, and PXA-R should not be limited to that shown in FIG. 1, and the arrangement order of the first pixel area PXA-G, the second pixel area PXA-B, and the third pixel area PXA-R may be provided in one or more suitable combinations according to display quality characteristics of the display device DD. As an example, the arrangement of the pixel areas PXA-G, PXA-B, and PXA-R may be a PENTILE® arrangement or a DIAMOND OLED® arrangement. PENTILE® and DIAMOND OLED® are registered trademarks of Samsung Display Co., Ltd.

The base substrate BS may be a member that provides a base surface on which the display element layer DP-ED is disposed. The base substrate BS may be a glass substrate, a metal substrate, or a plastic substrate. However, the present disclosure should not be limited thereto or thereby, and the base substrate BS may be an inorganic layer, an organic layer, or a composite material layer.

The circuit layer DP-CL may be disposed on the base layer BS and may include a plurality of transistors. Each of the transistors may include a control electrode, an input electrode, and an output electrode. As an example, the circuit layer DP-CL may include a switching transistor and a driving transistor to drive the first, second, and third light emitting elements ED1, ED2, and ED3.

The pixel definition layer PDL may be disposed on the circuit layer DP-CL. The pixel definition layer PDL may be formed of a polymer resin. As an example, the pixel definition layer PDL may include a polyacrylate-based resin or a polyimide-based resin. In one or more embodiments, the pixel definition layer PDL may further include an inorganic material in addition to the polymer resin. In one or more embodiments, the pixel definition layer PDL may include a light absorbing material or may include a black pigment or a black dye. The pixel definition layer PDL including the black pigment or the black dye may be implemented as a black pixel definition layer. When the pixel definition layer PDL is formed, a carbon black may be utilized as the black pigment or the black dye; however, the present disclosure should not be limited thereto or thereby.

In one or more embodiments, the pixel definition layer PDL may include an inorganic material. As an example, the pixel definition layer PDL may include silicon nitride (SiNₓ), silicon oxide (SiOₓ), or silicon oxynitride (SiOₓN_{y}).

Each of the first, second, and third light emitting elements ED1, ED2, and ED3 may include a first electrode EL1, a second electrode EL2 facing the first electrode EL1, and a plurality of light emitting stacks SF1, SF2, and SF3 disposed between the first electrode EL1 and the second electrode EL2 and stacked in the third direction DR3. Each of the light emitting stacks SF1, SF2, and SF3 may include an electron transport region, a light emitting layer, and a hole transport region. For example, each of the first, second, and third light emitting elements ED1, ED2, and ED3 included in the display device DD may be a light emitting element having a tandem structure in which each of the light emitting stacks includes a light emitting layer.

The number of the light emitting stacks SF1, SF2, and SF3 included in the first, second, and third light emitting elements ED1, ED2, and ED3 may be two or more. FIG. 2A shows the structure in which each of the first, second, and third light emitting elements ED1, ED2, and ED3 includes three light emitting stacks. In detail, each of the first, second, and third light emitting elements ED1, ED2, and ED3 may include the first electrode EL1, a first layer light emitting stack SF1, a second layer light emitting stack SF2, a third layer light emitting stack SF3, and the second electrode EL2, however, the present disclosure should not be limited thereto or thereby. According to one or more embodiments, each of the first, second, and third light emitting elements ED1, ED2, and ED3 may include two, four, or more stacks.

In one or more embodiments, each of the first, second, and third light emitting elements ED1, ED2, and ED3 may be to emit a light in a direction from the first electrode EL1 to the second electrode EL2. The first, second, and third light emitting elements ED1, ED2, and ED3 may have an inverted device structure in which the electron transport region is disposed under the light emitting layer EML and the hole transport region is disposed on the light emitting layer EML based on the direction in which the light is emitted.

According to one or more embodiments, the first, second, and third light emitting elements ED1, ED2, and ED3 may have substantially the same structure, at least one of the first, second, or third light emitting elements ED1, ED2, and ED3 may have a different structure from that of the other two light emitting elements of the first, second, and third light emitting elements ED1, ED2, and ED3, or all the first, second, and third light emitting elements ED1, ED2, and ED3 may have different structures from each other. As an example, according to the display device DD, the first light emitting element ED1 and the third light emitting element ED3 may have substantially the same structure, and the second light emitting element ED2 may have a structure different from those of the first light emitting element ED1 and the third light emitting element ED3. A bank BK may be disposed at a boundary of the second light emitting element ED2. As an example, the bank BK may be disposed between the first light emitting element ED1 and the second light emitting element ED2. The bank BK may be disposed between the second light emitting element ED2 and the third light emitting element ED3. Due to the bank BK, the second light emitting element ED2 may be distinguished from the first light emitting element ED1 and the third light emitting element ED3.

The bank BK may be disposed on the pixel definition layer PDL and may overlap a portion of the pixel definition layer PDL. The bank BK may be provided with a bank opening BK-OH defined therethrough. The electron transport region, the light emitting layer, and the hole transport region included in the light emitting stacks SF1, SF2, and SF3 may be patterned and provided in the bank opening BK-OH by an inkjet printing method, and the bank BK may include a liquid repellent material. According to one or more embodiments, the bank BK may include substantially the same material as that of the pixel definition layer PDL and may be provided integrally with the pixel definition layer PDL.

An encapsulation layer TFE may be disposed on the first, second, and third light emitting elements ED1, ED2, and ED3. The encapsulation layer TFE may cover the first, second, and third light emitting elements ED1, ED2, and ED3. The encapsulation layer TFE may encapsulate the display element layer DP-ED. The encapsulation layer TFE may be a thin film encapsulation layer. The encapsulation layer TFE may have a single-layer structure or a multilayer structure. The encapsulation layer TFE may include at least one insulating layer. According to one or more embodiments, the encapsulation layer TFE may include at least one inorganic layer (hereinafter, referred to as an encapsulation inorganic layer). According to one or more embodiments, the encapsulation layer TFE may include at least one organic layer (hereinafter, referred to as an encapsulation organic layer) and at least one encapsulation inorganic layer.

The encapsulation inorganic layer may protect the display element layer DP-ED from moisture and oxygen, and the encapsulation organic layer may protect the display element layer DP-ED from a foreign substance such as dust particles. The encapsulation inorganic layer may include silicon nitride, silicon oxynitride, silicon oxide, titanium oxide, or aluminum oxide; however, the present disclosure should not be particularly limited thereto. The encapsulation organic layer may include an acrylic-based compound or an epoxy-based compound. The encapsulation organic layer may include a photopolymerizable organic material; however, the present disclosure should not be limited thereto or thereby.

The upper display substrate 200 may be disposed on the encapsulation layer TFE. The upper display substrate 200 may include a base substrate BL, a color filter layer CFL, and a light control layer CCL.

The light control layer CCL may be disposed on the display panel 100. The light control layer CCL may include a light converter. The light converter may be a quantum dot or a fluorescent substance. The light converter may convert a wavelength of a light incident thereto and may be to emit the light having the converted wavelength. For example, the light control layer CCL may include the quantum dot or the fluorescent substance.

The light control layer CCL may include a plurality of light control portions CCP1, CCP2, and CCP3. The light control portions CCP1, CCP2, and CCP3 may be spaced apart from each other. As shown in drawings, a partition pattern BMP may be disposed between the light control portions CCP1, CCP2, and CCP3 spaced apart from each other; however, the present disclosure should not be limited thereto or thereby. FIG. 2A shows the partition pattern BMP that does not overlap the light control portions CCP1, CCP2, and CCP3. However, edges of the light control portions CCP1, CCP2, and CCP3 may overlap at least a portion of the partition pattern BMP.

According to one or more embodiments, the light control layer CCL may include a first light control portion CCP1, a second light control portion CCP2, and a third light control portion CCP3 to transmit or convert the light provided from the display panel 100. As an example, the first light control portion CCP1 may include a first quantum dot QD1 that converts a second light or a third light to a first light. The second light control portion CCP2 may be to transmit the second light. The third light control portion CCP3 may include a second quantum dot QD2 that converts the first light to the third light.

The quantum dot may have a core-shell structure, and a core of the quantum dot may include (e.g., may be selected from) a group II-VI compound, a group III-VI compound, a group I-III-VI compound, a group III-V compound, a group III-II-V compound, a group IV-VI compound, a group IV element, a group IV compound, and/or a combination thereof.

The group II-VI compound may include (e.g., may be selected from) a binary compound including (e.g., selected from the group consisting of) CdSe, CdTe, CdS, ZnS, ZnSe, ZnTe, ZnO, HgS, HgSe, HgTe, MgSe, MgS, and/or a mixture thereof, a ternary compound including (e.g., selected from the group consisting of) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or a mixture thereof, and/or a quaternary compound including (e.g., selected from the group consisting of) HgZnTeS, CdZnSeS, CdZnSeTe, CdZnSTe, CdHgSeS, CdHgSeTe, CdHgSTe, HgZnSeS, HgZnSeTe, HgZnSTe, and/or a mixture thereof.

The group III-VI compound may include a binary compound of In₂S₃ or In₂Se₃, a ternary compound of InGaS₃ or InGaSe₃, or a combination thereof.

The group I-III-VI compound may include a ternary compound including (e.g., selected from the group consisting of) AgInS, AgInS₂, CuInS, CuInS₂, AgGaS₂, CuGaS₂ CuGaO₂, AgGaO₂, AgAlO₂, and/or a mixture thereof, or a quaternary compound of AgInGaS₂, CuInGaS₂, and/or any other suitable compound.

The group III-V compound may include (e.g., may be selected from) a binary compound including (e.g., selected from the group consisting of) GaN, GaP, GaAs, GaSb, AlN, AlP, AlAs, AlSb, InN, InP, InAs, InSb, and/or a mixture thereof, a ternary compound including (e.g., selected from the group consisting of) GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and/or a mixture thereof, and/or a quaternary compound including (e.g., selected from the group consisting of) GaAlNP, GaAlNAs, GaAlNSb, GaAlPAs, GaAlPSb, GalnNP, GalnNAs, GalnNSb, GalnPAs, GalnPSb, InAlNP, InAlNAs, InAlNSb, InAlPAs, InAlPSb, and/or a mixture thereof. The group III-V compound may further include a group II metal. For instance, InZnP, InGaZnP, and/or InAlZnP may be included as (e.g., selected as) the group III-II-V compound.

The group IV-VI compound may include (e.g., may be selected from) a binary compound including (e.g., selected from the group consisting of) SnS, SnSe, SnTe, PbS, PbSe, PbTe, and/or a mixture thereof, a ternary compound including (e.g., selected from the group consisting of) SnSeS, SnSeTe, SnSTe, PbSeS, PbSeTe, PbSTe, SnPbS, SnPbSe, SnPbTe, and/or a mixture thereof, and/or a quaternary compound including (e.g., selected from the group consisting of) SnPbSSe, SnPbSeTe, SnPbSTe, and/or a mixture thereof. The group IV element may include (e.g., may be selected from the group consisting of) Si, Ge, and/or a mixture thereof. The group IV compound may be a binary compound including (e.g., selected from the group consisting of) SiC, SiGe, and/or a mixture thereof.

In this case, the binary compound, the ternary compound, or the quaternary compound may exist in the particles at a substantially uniform concentration or may exist in substantially the same particle after being divided into plural (e.g., multiple) portions having different concentrations. In one or more embodiments, the quantum dots may have a core/shell structure in which one quantum dot is around (e.g., surrounds) another quantum dot. In the core/shell structure, the concentration of elements existing in the shell may have a concentration gradient that is lowered as the distance from the core decreases.

The shell of the quantum dot may serve as a protective layer to prevent or reduce chemical modification of the core and to maintain semiconductor properties and/or may serve as a charging layer to impart electrophoretic properties to the quantum dot. The shell may have a single-layer or multilayer structure. The shell of the quantum dots may include metal oxides, non-metal oxides, semiconductor compounds, or combinations thereof, as a representative example.

The metal oxides or the non-metal oxides may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound, such as MgAl₂O₄, CoFe₂O₄, NiFe₂O₄, and/or CoMn₂O₄; however, the present disclosure should not be limited thereto or thereby.

In one or more embodiments, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and/or AlSb; however, the present disclosure should not be limited thereto or thereby.

The quantum dots may have a full width of half maximum (FWHM) of the light emission wavelength spectrum of about 45 nm or less, about 40 nm or less, or, in one or more embodiments, about 30 nm or less. The color purity and the color reproducibility may be improved within this range. In one or more embodiments, because the light emitted through the quantum dots may be emitted in all directions, an optical viewing angle may be improved.

In one or more embodiments, the shape of the quantum dots may have a shape commonly utilized in the art; however, the present disclosure should not be particularly limited. In one or more embodiments, spherical, pyramidal, multi-arm, and/or cubic nanoparticles, nanotubes, nanowires, nanofibers, nanoplatelets, and/or the like may be applied to the quantum dots.

The quantum dots may control the color of the emitted light depending on a particle size thereof, and accordingly, the quantum dots may have one or more suitable emission colors such as blue, red, and green colors.

As an example, the first quantum dot QD1 included in the first light control portion CCP1 may be a green quantum dot, and the second quantum dot QD2 included in the third light control portion CCP3 may be a red quantum dot. However, the light control layer CCL should not be limited thereto or thereby, and the second light control portion CCP2 may include the quantum dot.

In one or more embodiments, the light control layer CCL may include a scatterer SP. The first light control portion CCP1 may include at least one of the first quantum dot QD1 or the scatterer SP, the third light control portion CCP3 may include at least one of the second quantum dot QD2 or the scatterer SP, and the second light control portion CCP2 may include the scatterer SP.

The scatterer SP may be an inorganic particle. As an example, the scatterer SP may include at least one of TiO₂, ZnO, Al₂O₃, SiO₂, or a hollow silica. The scatterer SP may include one of TiO₂, ZnO, Al₂O₃, SiO₂, or the hollow silica or may include a mixed material of two or more of TiO₂, ZnO, Al₂O₃, SiO₂, and/or the hollow silica.

The first light control portion CCP1, the second light control portion CCP2, and the third light control portion CCP3 may respectively include base resins BR1, BR2, and BR3 in which the scatterer SP and/or quantum dot QD1 and QD2 are dispersed. In one or more embodiments, the first light control portion CCP1 may include the first quantum dot QD1 and the scatterer SP, which are dispersed in a first base resin BR1, the third light control portion CCP3 may include the second quantum dot QD2 and the scatterer SP, which are dispersed in a third base resin BR3, and the second light control portion CCP2 may include the scatterer SP dispersed in a second base resin BR2.

The base resins BR1, BR2, and BR3 may be a medium in which the quantum dots QD1 and QD2 and/or the scatterer SP are dispersed, and may include one or more suitable resin compositions that are generally referred to as binders. As an example, the base resins BR1, BR2, and BR3 may be an acrylic-based resin, a urethane-based resin, a silicone-based resin, or an epoxy-based resin. The base resins BR1, BR2, and BR3 may be transparent resins. According to one or more embodiments, the first base resin BR1, the second base resin BR2, and the third base resin BR3 may be substantially the same as each other or may be different from each other.

The light control layer CCL may include a barrier layer BFL1. The barrier layer BFL1 may prevent or substantially prevent moisture and oxygen from entering therein. The barrier layer BFL1 may be disposed on the light control portions CCP1, CCP2, and CCP3 and may prevent or substantially prevent the light control portions CCP1, CCP2, and CCP3 from being exposed to moisture and oxygen. In one or more embodiments, the barrier layer BFL1 may cover the light control portions CCP1, CCP2, and CCP3. In one or more embodiments, a barrier layer BFL2 may be disposed between the light control portions CCP1, CCP2, and CCP3 and the color filters CF1, CF2, and CF3, (e.g., in the DR3 or thickness direction).

The barrier layers BFL1 and BFL2 may include at least one inorganic layer. For example, the barrier layers BFL1 and BFL2 may include an inorganic material. As an example, the barrier layers BFL1 and BFL2 may include silicon nitride, aluminum nitride, zirconium nitride, titanium nitride, hafnium nitride, tantalum nitride, silicon oxide, aluminum oxide, titanium oxide, tin oxide, cerium oxide, and/or silicon oxynitride, and/or a metal thin film having a light transmittance property. In one or more embodiments, the barrier layers BFL1 and BFL2 may further include an organic layer. The barrier layers BFL1 and BFL2 may have a single-layer or multilayer structure.

In the display device DD, the color filter layer CFL may be disposed on the light control layer CCL. As an example, the color filter layer CFL may be disposed directly on the light control layer CCL. In this case, the barrier layer BFL2 may not be provided.

The color filter layer CFL may include a light blocking portion BM and the color filters CF1, CF3, and CF3. In one or more embodiments, the color filter layer CFL may include a first color filter CF1 transmitting the first light, a second color filter CF2 transmitting the second light, and a third color filter CF3 transmitting the third light. As an example, the first color filter CF1 may be a green color filter, the second color filter CF2 may be a blue color filter, and the third color filter CF3 may be a red color filter. Each of the first, second, and third color filters CF1, CF2, and CF3 may include a polymer photoresist and a pigment or dye. The first color filter CF1 may include a green pigment or dye, the second color filter CF2 may include a blue pigment or dye, and the third color filter CF3 may include a red pigment or dye; however, the present disclosure should not be limited thereto or thereby. According to one or more embodiments, the second color filter CF2 may not include (e.g., may exclude) the pigment or dye. The second color filter CF2 may include the polymer photoresist and may not include (e.g., may exclude) the pigment or dye.

The light blocking portion BM may be a black matrix. The light blocking portion BM may be formed of an organic light blocking material or an inorganic light blocking material, which includes a black pigment or a black dye. The light blocking portion BM may prevent or substantially prevent a light leakage phenomenon from occurring and may define a boundary between the color filters CF1, CF2, and CF3. The light blocking portion BM may be implemented by a blue filter.

The first, second, and third color filters CF1, CF2, and CF3 may be disposed to correspond to the first pixel area PXA-G, the second pixel area PXA-B, the third pixel area PXA-R, respectively.

The base substrate BL may provide a base surface on which the color filter layer CFL and the light control layer CCL are disposed. The base substrate BL may be a glass substrate, a metal substrate, or a plastic substrate. However, the present disclosure should not be limited thereto or thereby, and the base substrate BL may be an inorganic layer, an organic layer and/or a composite material layer. In one or more embodiments, the base substrate BL may not be provided. When the base substrate BL is omitted, the light control layer CCL and the color filter layer CFL may be sequentially stacked on the encapsulation layer TFE of the display panel 100.

In one or more embodiments, configurations of the upper display substrate 200 should not be limited thereto or thereby. As an example, the upper display substrate 200 may further include a polarizing layer, and the color filter layer CFL may not be provided. The polarizing layer may block or substantially block an external light incident into the display device DD from the outside of the display device DD. As an example, the polarizing layer may block or substantially block a reflected light generated by the external light that is incident into the display panel 100 from the outside of the display device DD, reflected by a lower component such as the first electrode or the second electrode, and emitted to the outside.

Referring to FIG. 2B, the circuit layer DP-CL of the display device DD may include a buffer layer BFL, a first gate insulating layer GI1, a second gate insulating layer GI2, an interlayer insulating layer ILD, an upper insulating layer VIA1, a semiconductor pattern ACP including a plurality of patterns, a first conductive layer CLP1 including a plurality of patterns, a second conductive layer CLP2 including a plurality of patterns, and a third conductive layer CLP3 including a plurality of patterns. In this case, the first conductive layer CLP1 may include a first gate metal pattern, the second conductive layer CLP2 may include a second gate metal pattern, and the third conductive layer CLP3 may include a first data metal pattern.

According to one or more embodiments, each of the first gate insulating layer GI1, the second gate insulating layer GI2, and/or the interlayer insulating layer ILD may include an organic layer and/or an inorganic layer. According to one or more embodiments, each of the first gate insulating layer GI1, the second gate insulating layer GI2, and/or the interlayer insulating layer ILD may include a plurality of inorganic thin layers. The inorganic thin layers may include a silicon nitride layer and/or a silicon oxide layer. According to one or more embodiments, each of the first conductive layer CLP1 and/or the second conductive layer CLP2 may include molybdenum (Mo); however, the present disclosure should not be limited thereto or thereby.

According to one or more embodiments, the third conductive layer CLP3 may include at least one of aluminum (Al) or titanium (Ti); however, the present disclosure should not be limited thereto or thereby. According to one or more embodiments, the third conductive layer CLP3 may have a structure in which titanium, aluminum, and titanium are sequentially stacked.

The buffer layer BFL may be disposed on the base layer BS. The buffer layer BFL may include a first buffer layer and a second buffer layer. The second buffer layer may be disposed on the first buffer layer. The buffer layer BFL may prevent or substantially prevent a foreign substance on the base layer BS from entering the pixel PX. In one or more embodiments, the buffer layer BFL may prevent or substantially prevent the foreign substance from being diffused to the semiconductor pattern ACP of transistors T1 and T2 of the pixel PX.

The foreign substance may be introduced from the outside or may be generated during a thermal decomposition of the base layer BS. The foreign substance may be sodium or gas emitted from the base layer BS. In one or more embodiments, the buffer layer BFL may block or substantially block moisture from entering the pixel PX from the outside.

The semiconductor pattern ACP may be disposed on the buffer layer BFL. According to one or more embodiments, the semiconductor pattern ACP may be disposed on the buffer layer BFL.

The semiconductor pattern ACP may form each of the transistors T1 and T2. The semiconductor pattern ACP may include polysilicon, amorphous silicon, and/or metal oxide semiconductor. FIG. 2B shows a semiconductor pattern forming a source S1, an active C1, and a drain D1 of a first transistor T1 and a semiconductor pattern forming a source S2, an active C2, and a drain D2 of a second transistor T2.

The first gate insulating layer GI1 may be disposed on the buffer layer BFL and may cover the semiconductor pattern ACP. The first conductive layer CLP1 may be disposed on the first gate insulating layer GI1. A gate G1 of the first transistor T1 and a gate G2 of the second transistor T2 are shown as the first conductive layer CLP1. In one or more embodiments, the first conductive layer CLP1 may include one of two electrodes forming a capacitor of the pixel PX.

The second gate insulating layer GI2 may be disposed on the first gate insulating layer GI1 and may cover the first conductive layer CLP1. The second conductive layer CLP2 may be disposed on the second gate insulating layer GI2. According to one or more embodiments, the second conductive layer CLP2 may be the other electrode of the two electrodes of the capacitor CP of the pixel PX. An upper electrode UE may be shown as the second conductive layer CLP2.

The interlayer insulating layer ILD may be disposed on the second gate insulating layer GI2 and may cover the second conductive layer CLP2. A first connection electrode CNE-D1 of the third conductive layer CLP3 may be connected to the source S2 of the second transistor T2. The upper insulating layer VIA1 may be disposed on the interlayer insulating layer ILD and may cover the third conductive layer CLP3.

As shown in FIG. 2B, the display element layer DP-ED may include the light emitting element and the pixel definition layer PDL. As shown in FIG. 2B, the second light emitting element ED2 may be disposed on the cross-section taken along the line II-II′ of FIG. 1, and the second light emitting element ED2 may include the light emitting stacks SF1, SF2, and SF3 disposed between the first electrode EL1 and the second electrode EL2 as described above.

The first electrode EL1 may be disposed on the upper insulating layer VIA1. The first electrode EL1 may be electrically connected to at least one of the transistors T1 or T2 via a contact hole. The first electrode EL1 may be connected to the first connection electrode CNE-D1 via the contact hole and may be electrically connected to the second transistor T2. According to one or more embodiments of the present disclosure, at least one of the transistors T1 or T2 may be an NMOS transistor. According to one or more embodiments, the transistor electrically connected to the first electrode EL1 may be the NMOS transistor. For example, the second transistor T2 may be the NMOS transistor.

The first electrode EL1 may be a transmissive electrode, a transflective electrode, or a reflective electrode. The first electrode EL1 may include at least one of (e.g., one selected from among) Ag, Mg, Cu, Al, Pt, Pd, Au, Ni, Nd, Ir, Cr, Li, Ca, LiF, Mo, Ti, W, In, Sn, and/or Zn, a compound of two or more including (e.g., selected from among) these, a mixture of two or more including (e.g., selected from among) these, and/or an oxide thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (e.g., a mixture of Ag and Mg). In one or more embodiments, the first electrode EL1 may have a multilayer structure including a reflective film or a transflective film formed of the above-described materials, and/or a transparent conductive film formed of ITO, IZO, ZnO, ITZO, and/or any other suitable transparent conductive film. For example, the first electrode EL1 may have a three-layer structure of ITO/Ag/ITO, but the present disclosure is not limited thereto. In one or more embodiments, the first electrode EL1 may include the above-described metal materials, combinations of at least two metal materials of the above-described metal materials, oxides of the above-described metal materials, and/or the like.

The pixel definition layer PDL may be disposed on the upper insulating layer VIA1, and at least a portion of the first electrode EL1 may be exposed without being covered by the pixel definition layer PDL. The light emitting stacks SF1, SF2, and SF3 may be disposed on the first electrode EL1. The second electrode EL2 may be disposed on the light emitting stacks SF1, SF2, and SF3.

The second electrode EL2 may be a cathode or an anode, but the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or any other suitable transparent metal oxide.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, or a compound or mixture thereof (e.g., AgMg, AgYb, or MgAg). In one or more embodiments, the second electrode EL2 may have a multilayer structure including a reflective film or a transflective film formed of the above-described materials, and a transparent conductive film formed of ITO, IZO, ZnO, ITZO, or any other suitable transparent conductive film. For example, the second electrode EL2 may include the above-described metal materials, combinations of at least two metal materials of the above-described metal materials, oxides of the above-described metal materials, and/or the like.

FIGS. 2C to 2F are plan views of some components of the display device according to one or more embodiments of the present disclosure. FIGS. 2C to 2F show arrangements of the pixel definition layer PDL, the bank BK, functional layers FL1 and FL2, and light emitting layers EML-G and EML-B in three pixel areas PXA-G, PXA-B, and PXA-R adjacent to each other and the non-pixel area NPXA around (e.g., surrounding) the three pixel areas PXA-G, PXA-B, and PXA-R when viewed in a plane (e.g., in a plan view).

Referring to FIGS. 2A and 2C, the pixel opening PDL-OH may be defined through the pixel definition layer PDL, and the pixel areas PXA-G, PXA-B, and PXA-R may be distinguished from each other by the pixel opening PDL-OH. The pixel definition layer PDL may be disposed to entirely overlap the non-pixel area NPXA, and the pixel opening PDL-OH defined through the pixel definition layer PDL may overlap each of the pixel areas PXA-G, PXA-B, and PXA-R.

Referring to FIGS. 2A, 2C, and 2D, the bank opening BK-OH may be defined through the bank BK, and the light emitting stacks SF1, SF2, and SF3 may be disposed in the bank opening BK-OH. The bank BK may overlap a portion of the non-pixel area NPXA and may not overlap another portion of the non-pixel area NPXA. In one or more embodiments, the bank BK may not overlap a portion of the non-pixel area NPXA, which is disposed between the first pixel area PXA-G and the third pixel area PXA-R. For example, the bank opening BK-OH defined through the bank BK may overlap each of the pixel areas PXA-G, PXA-B, and PXA-R and may also overlap the portion of the non-pixel area NPXA, which is disposed between the first pixel area PXA-G and the third pixel area PXA-R. As shown in FIG. 2D, the bank opening BK-OH may include a first bank opening BK-OH1 extending to overlap all the first pixel area PXA-G, the third pixel area PXA-R, and the non-pixel area NPXA disposed therebetween and a second bank opening BK-OH2 overlapping the second pixel area PXA-B.

Referring to FIGS. 2A and 2C to 2F, each of the light emitting stacks SF1, SF2, and SF3 may include the functional layers FL1 and FL2 including the electron transport region and the hole transport region and the light emitting layers EML-G and EML-B including a light emitting material. The functional layers FL1 and FL2 may include an electron injection layer, an electron transport layer, a hole blocking layer, a hole transport layer, a hole injection layer, and a buffer layer, which are included in the electron transport region and the hole transport region.

Each of the functional layers FL1 and FL2 and the light emitting layers EML-G and EML-B may be disposed in the bank opening BK-OH defined through the bank BK. According to one or more embodiments, the functional layers FL1 and FL2 may include a first functional layer FL1 disposed in the first bank opening BK-OH1 and a second functional layer FL2 disposed in the second bank opening BK-OH2. The light emitting layers EML-G and EML-B may include a first light emitting layer EML-G disposed in the first bank opening BK-OH1 and a second light emitting layer EML-B disposed in the second bank opening BK-OH2. Each of the first functional layer FL1 and the first light emitting layer EML-G may be disposed to overlap both the first pixel area PXA-G and the third pixel area PXA-R and to overlap the non-pixel area NPXA disposed between the first pixel area PXA-G and the third pixel area PXA-R. The second functional layer FL2 and the second light emitting layer EML-B may be disposed to overlap the second pixel area PXA-B. The first light emitting layer EML-G may include the light emitting material that emits at least the first light, e.g., the green light. The second light emitting layer EML-B may include the light emitting material that emits the second light, e.g., the blue light.

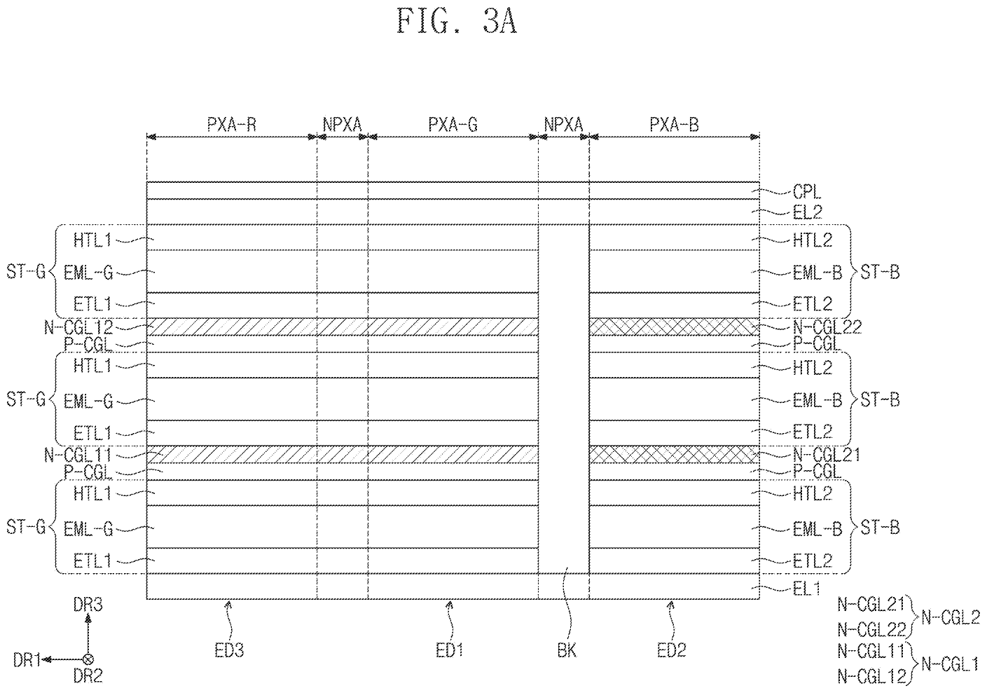

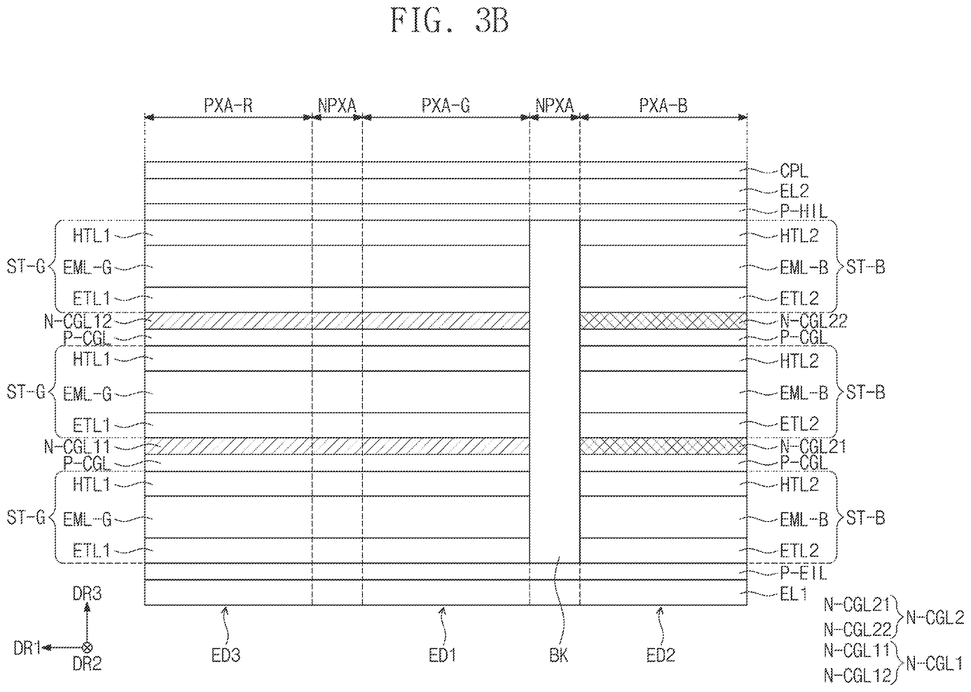

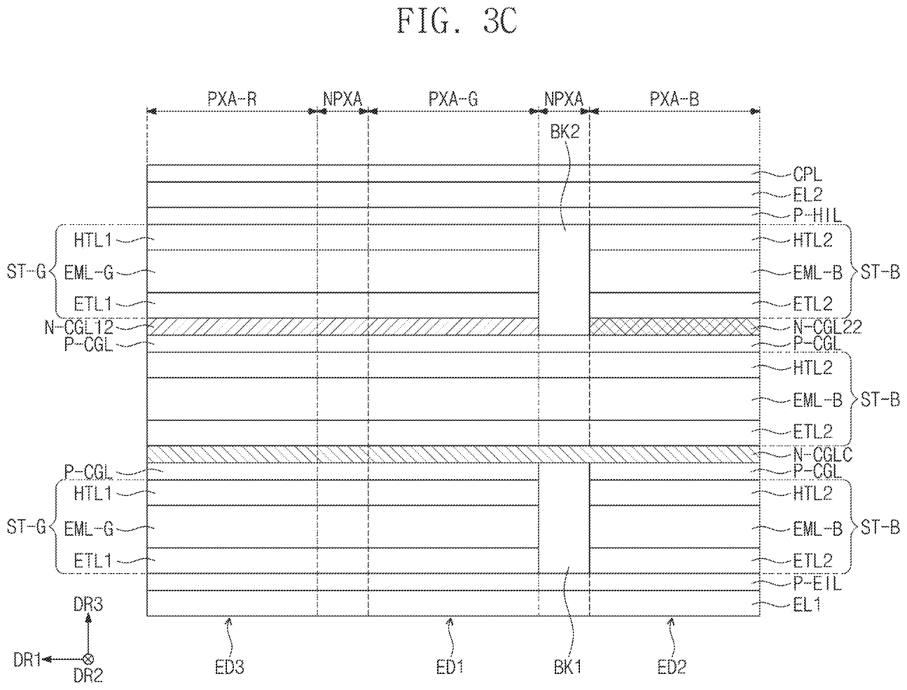

FIGS. 3A to 3C are cross-sectional views of light emitting elements according to one or more embodiments of the present disclosure. FIGS. 3A to 3C show the first, second, and third light emitting elements ED1, ED2, and ED3 included in the display device DD shown in FIG. 2A. FIGS. 3A to 3C show structures in which a capping layer CPL is further disposed on the first, second, and third light emitting elements ED1, ED2, and ED3. The capping layer CPL may have a single-layer or multilayer structure. The capping layer CPL may include an organic layer or an inorganic layer. As an example, the inorganic layer included in the capping layer CPL may include an alkali metal compound such as LiF, an alkaline earth metal compound such as MgF2, SiON, SiNx, SiOy, and/or any other suitable compound or material.

As an example, the organic layer included in the capping layer CPL may include α-NPD, NPB, TPD, m-MTDATA, Alq₃, CuPc, TPD15(N4,N4,N4′,N4′-tetra (biphenyl-4-yl) biphenyl-4,4′-diamine), TCTA(4,4′,4″-Tris (carbazol-9-yl) triphenylamine), and/or the like, or may include an epoxy resin or an acrylate, such as methacrylate; however, the present disclosure should not be limited thereto or thereby. According to one or more embodiments, the capping layer CPL may include at least one of the following compounds P1 to P5.

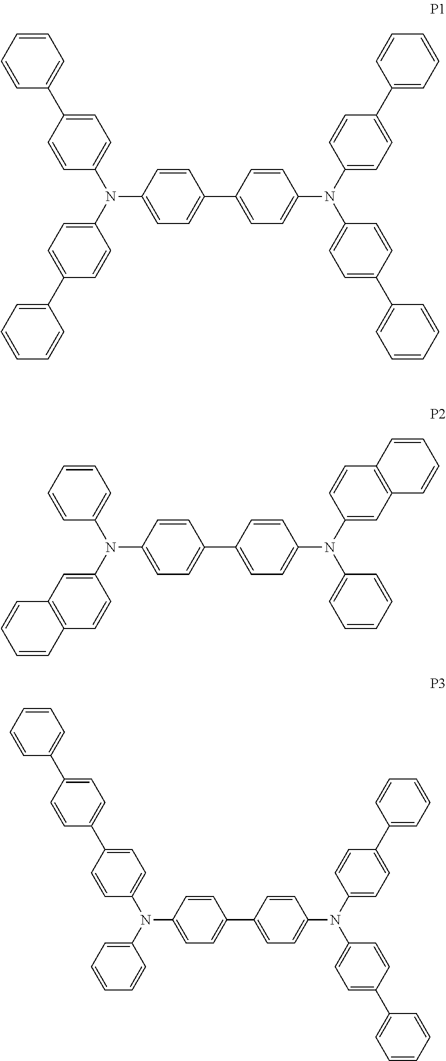 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

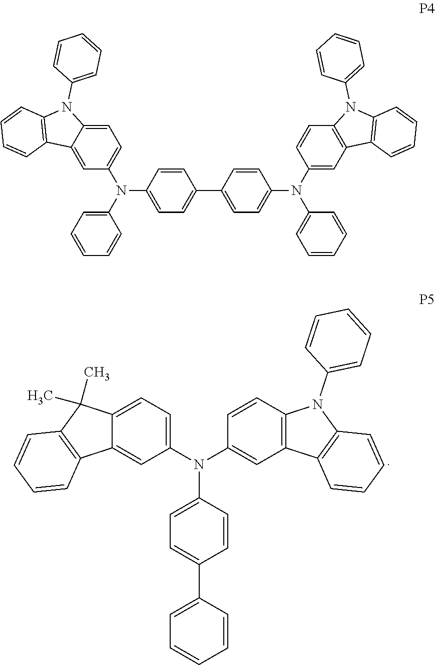 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc4c(c3)c3ccccc3n4-c3ccccc3)ccc21]

However, the present disclosure should not be limited thereto or thereby. According to one or more embodiments, the capping layer CPL may not be provided.

FIGS. 2A and 3A show the structure in which each of the first, second, and third light emitting elements ED1, ED2, and ED3 includes three light emitting stacks. In one or more embodiments, each of the first, second, and third light emitting elements ED1, ED2, and ED3 may include three stacks corresponding to the first, second, and third layer light emitting stacks SF1, SF2, and SF3 described with reference to FIG. 2B; however, the present disclosure should not be limited thereto or thereby. According to one or more embodiments, each of the first, second, and third light emitting elements ED1, ED2, and ED3 may include two light emitting stacks or may include four or more light emitting stacks.

Referring to FIGS. 2A and 3A, each of the first, second, and third light emitting elements ED1, ED2, and ED3 may include a first light emitting stack ST-G or a second light emitting stack ST-B. According to one or more embodiments, the first light emitting stack ST-G may include the first light emitting layer EML-G emitting the green light as the first light, the second light emitting stack ST-B may include the second light emitting layer EML-B emitting the blue light as the second light.

According to one or more embodiments, the first light emitting element ED1 may include the first light emitting stack ST-G as the first layer light emitting stack SF1 described with reference to FIGS. 2A and 2B, may include the first light emitting stack ST-G as the second layer light emitting stack SF2 described with reference to FIGS. 2A and 2B, and may include the first light emitting stack ST-G as the third layer light emitting stack SF3 described with reference to FIGS. 2A and 2B. For example, the first light emitting element ED1 may include three first light emitting stacks ST-G sequentially stacked; however, the present disclosure should not be limited thereto or thereby. According to one or more embodiments, the first light emitting element ED1 may include one or more second light emitting stacks ST-B. As an example, the first light emitting element ED1 may include the second light emitting stack ST-B as the first layer light emitting stack SF1. According to one or more embodiments, the first light emitting element ED1 may include four light emitting stacks, for example, three second light emitting stacks ST-B and one first light emitting stack ST-G.

The second light emitting element ED2 may include the second light emitting stack ST-B as the first layer light emitting stack SF1 described with reference to FIGS. 2A and 2B, may include the second light emitting stack ST-B as the second layer light emitting stack SF2 described with reference to FIGS. 2A and 2B, and may include the second light emitting stack ST-B as the third layer light emitting stack SF3 described with reference to FIGS. 2A and 2B. For example, the second light emitting element ED2 may include three second light emitting stacks ST-B sequentially stacked; however, the present disclosure should not be limited thereto or thereby. According to one or more embodiments, the second light emitting element ED2 may include one or more first light emitting stacks ST-G. As an example, the second light emitting element ED2 may include four light emitting stacks, e.g., three second light emitting stacks ST-B and one first light emitting stack ST-G.

Each of the first light emitting stacks ST-G and the second light emitting stacks ST-B may include the hole transport region, the light emitting layer, and the electron transport region. FIG. 3A schematically shows a structure in which the electron transport region includes the electron transport layer and the hole transport region includes the hole transport layer. As an example, the first light emitting stack ST-G may include a first electron transport layer ETL1, the first light emitting layer EML-G, and a first hole transport layer HTL1. The first light emitting layer EML-G may be to emit the first light. As an example, the second light emitting stack ST-B may include a second electron transport layer ETL2, the second light emitting layer EML-B, and a second hole transport layer HTL2. The second light emitting layer EML-B may be to emit the second light. However, the present disclosure should not be limited thereto or thereby. According to one or more embodiments, each of the first light emitting stack ST-G and/or the second light emitting stack ST-B may further include the electron injection layer, the hole blocking layer, the hole injection layer, the electron blocking layer, and/or the buffer layer.

The third light emitting element ED3 may have substantially the same stack structure as that of the first light emitting element ED1. For example, the third light emitting element ED3 may include the first light emitting stack ST-G as the first layer light emitting stack SF1 described with reference to FIGS. 2A and 2B, may include the first light emitting stack ST-G as the second layer light emitting stack SF2 described with reference to FIGS. 2A and 2B, and may include the first light emitting stack ST-G as the third layer light emitting stack SF3 described with reference to FIGS. 2A and 2B. For example, the third light emitting element ED3 may include three first light emitting stacks ST-G sequentially stacked.

The light emitting stacks included in the first light emitting element ED1 may be integrally connected to the light emitting stacks included in the third light emitting element ED3, respectively. For example, the first light emitting stacks ST-G included in the first light emitting element ED1 may be provided integrally with the first light emitting stacks ST-G included in the third light emitting element ED3, respectively. The first light emitting stacks ST-G may extend to overlap the first pixel area PXA-G, the third pixel area PXA-R, and the non-pixel area NPXA disposed between the first pixel area PXA-G and the third pixel area PXA-R. Each of the first electron transport layer ETL1, the first light emitting layer EML-G, and/or the first hole transport layer HTL1 included in each of the first light emitting stacks ST-G may extend to overlap the first pixel area PXA-G, the third pixel area PXA-R, and/or the non-pixel area NPXA disposed between the first pixel area PXA-G and the third pixel area PXA-R.

According to one or more embodiments, each of the first, second, and third light emitting elements ED1, ED2, and ED3 may be to emit the light in the direction from the first electrode EL1 to the second electrode EL2 and may have the inverted device structure in which the electron transport region is disposed under the light emitting layer EML and the hole transport region is disposed on the light emitting layer EML in the direction in which the light is emitted. For example, each of the first light emitting stacks ST-G included in the first light emitting element ED1 and the third light emitting element ED3 may include the first electron transport layer ETL1 disposed adjacent to the first electrode EL1, the first light emitting layer EML-G disposed on the first electron transport layer ETL1, and the first hole transport layer HTL1 spaced apart from the first electron transport layer ETL1 with the first light emitting layer EML-G interposed therebetween and disposed adjacent to the second electrode EL2. Each of the second light emitting stacks ST-B included in the second light emitting element ED2 may include the second electron transport layer ETL2 disposed adjacent to the first electrode EL1, the second light emitting layer EML-B disposed on the second electron transport layer ETL2, and the second hole transport layer HTL2 spaced apart from the second electron transport layer ETL2 with the second light emitting layer EML-B interposed therebetween and disposed adjacent to the second electrode EL2.

A charge generation layer may be disposed between the light emitting stacks ST-G and between the light emitting stacks ST-B. In one or more embodiments , a p-type or kind charge generation layer (e.g., a P-charge generation layer) P-CGL and an n-type or kind charge generation layer (e.g., a N-charge generation layer) N-CGL1 may be stacked between the light emitting stacks ST-G, and the p-type or kind charge generation layer P-CGL and an n-type or kind charge generation layer N-CGL2 may be stacked between the light emitting stacks ST-B. The p-type or kind charge generation layer P-CGL and the n-type or kind charge generation layers N-CGL1 and N-CGL2 may facilitate the migration of holes and/or charges between the light emitting stacks ST-G and ST-B. Each of the charge generation layers P-CGL, N-CGL1, and N-CGL2 may be disposed to be in contact with one of the light emitting stacks ST-G and ST-B.

According to one or more embodiments, at least a portion of the charge generation layer disposed between the first light emitting stacks ST-G and at least a portion of the charge generation layer disposed between the second light emitting stacks ST-B may include different materials from each other. As the charge generation layers disposed between the light emitting stacks disposed in different pixel areas from each other in the display device DD include different materials, charge generation characteristics may be adjusted. According to one or more embodiments, an n-type or kind first charge generation layer N-CGL1 of the charge generation layer disposed between the first light emitting stacks ST-G may include a material different from a material of an n-type or kind second charge generation layer N-CGL2 of the charge generation layer disposed between the second light emitting stacks ST-B.

The p-type or kind charge generation layer P-CGL may include an organic dopant. The organic dopant may be, for example, a p-type or kind dopant. In one or more embodiments, the p-type or kind dopant may include at least one of 4-[[2,3-bis[cyano-(4-cyano-2,3,5,6-tetrafluorophenyl)methylidene]cyclopropylidene]-cyanomethyl]-2,3,5,6- tetrafluorobenzonitrile (hereinafter, referred to as NDP9), 1,4,5,8,9,11-hexaazatriphenylene-hexacarbonitrile (HAT-CN), 2,3,5,6-tetrafluoro-7,7,8,8-tetracyanoquinodimethane (F4-TCNQ), or tetracyanoquinodimethane (TCNQ). The organic dopant included in the p-type or kind charge generation layer P-CGL may include an organic material with a highest occupied molecular orbital (HOMO) level equal to or greater than about −6.0 eV and/or equal to or smaller than about −4.0 eV. According to one or more embodiments, the organic dopant included in the p-type or kind charge generation layer P-CGL may have a doping concentration equal to or greater than about 0.5% and/or equal to or smaller than about 30%.

The n-type or kind charge generation layers N-CGL1 and N-CGL2 may include the n-type or kind first charge generation layer N-CGL1 disposed between the first light emitting stacks ST-G and the n-type or kind second charge generation layer N-CGL2 disposed between the second light emitting stacks ST-B. The n-type or kind first charge generation layer N-CGL1 may include an n-type or kind first-1 charge generation layer N-CGL11 that is in contact with a lower surface of the second layer light emitting stack SF2 and an n-type or kind first-2 charge generation layer N-CGL12 that is in contact with a lower surface of the third layer light emitting stack SF3. The n-type or kind second charge generation layer N-CGL2 may include an n-type or kind second-1 charge generation layer N-CGL21 that is in contact with the lower surface of the second layer light emitting stack SF2 and an n-type or kind second-2 charge generation layer N-CGL22 that is in contact with the lower surface of the third layer light emitting stack SF3.

The n-type or kind first charge generation layer N-CGL1 may be disposed spaced apart from the n-type or kind second charge generation layer N-CGL2 by the bank BK. The n-type or kind first charge generation layer N-CGL1 may overlap the first pixel area PXA-G and the third pixel area PXA-R and may not overlap the second pixel area PXA-B. The n-type or kind second charge generation layer N-CGL2 may overlap the second pixel area PXA-B and may not overlap the first pixel area PXA-G and the third pixel area PXA-R. The n-type or kind first charge generation layer N-CGL1 may overlap a portion of the non-pixel area NPXA disposed between the first pixel area PXA-G and the third pixel area PXA-R.

The dopant material included in the n-type or kind first charge generation layer N-CGL1 may be different from the dopant material included in the n-type or kind second charge generation layer N-CGL2. According to one or more embodiments, the n-type or kind first charge generation layer N-CGL1 may include a first metal as its dopant, and the n-type or kind second charge generation layer N-CGL2 may include a second metal as its dopant. The n-type or kind first charge generation layer N-CGL1 and the n-type or kind second charge generation layer N-CGL2 may be doped with a dopant metal material at different rates.

The first metal may include, for example, ytterbium (Yb). The second metal may include other metals rather than ytterbium (Yb). The second metal may include a metal with a work function equal to or greater than about 1.7 eV and/or equal to or smaller than about 3.2 eV among metals except ytterbium (Yb). The second metal may include at least one of (e.g., one selected from the group consisting of) lithium (Li), potassium (K), rubidium (Rb), cesium (Cs), barium (Ba), europium (Eu), sodium (Na), strontium (Sr), samarium (Sm), calcium (Ca), terbium (Tb), and/or cerium (Ce). As an example, the second metal may include lithium (Li) or calcium (Ca).

According to one or more embodiments, each of the first metal and the second metal included in the n-type or kind charge generation layers N-CGL1 and N-CGL2 may have a doping concentration equal to or greater than about 0.5% and/or equal to or smaller than about 30%. The doping concentration of the first metal included in the n-type or kind first charge generation layer N-CGL1 may be equal to or greater than about 1% and/or equal to or smaller than about 10%. The doping concentration of the second metal included in the n-type or kind second charge generation layer N-CGL2 may be equal to or greater than about 1% and/or equal to or smaller than about 10%.

The second metal may have an electrical conductivity different from that of the first metal. According to one or more embodiments, the second metal may have the electrical conductivity higher than that of the first metal. As an example, the n-type or kind first charge generation layer N-CGL1 may include ytterbium, and the n-type or kind second charge generation layer N-CGL2 may include lithium having the electrical conductivity higher than that of ytterbium.

Referring to FIG. 3B, the display device DD may further include an electron injection doping layer P-EIL disposed on the first electrode EL1 and disposed under the first light emitting stacks ST-G and the second light emitting stacks ST-B. The display device DD may include a hole injection doping layer P-HIL disposed on the first light emitting stacks ST-G and the second light emitting stacks ST-B and disposed under the second electrode EL2.

Each of the electron injection doping layer P-EIL and the hole injection doping layer P-HIL may overlap all the first pixel area PXA-G, the second pixel area PXA-B, and the third pixel area PXA-R. For example, each of the electron injection doping layer P-EIL and the hole injection doping layer P-HIL may be provided as a common layer that entirely overlaps the first pixel area PXA-G, the second pixel area PXA-B, and the third pixel area PXA-R and the non-pixel area NPXA disposed between the first pixel area PXA-G, the second pixel area PXA-B, and the third pixel area PXA-R; however, the present disclosure should not be limited thereto or thereby. According to one or more embodiments, each of the electron injection doping layer P-EIL and the hole injection doping layer P-HIL may be patterned and provided in each of the first pixel area PXA-G, the second pixel area PXA-B, and the third pixel area PXA-R and may not overlap the non-pixel area NPXA.

The electron injection doping layer P-EIL may include a metal dopant having a work function equal to or greater than about 1.7 eV and/or equal to or smaller than about 3.2 eV and high electrical conductivity. The metal dopant may include at least one of (e.g., one selected from the group consisting of) ytterbium (Yb), lithium (Li), potassium (K), rubidium (Rb), cesium (Cs), barium (Ba), europium (Eu), sodium (Na), strontium (Sr), samarium (Sm), calcium (Ca), terbium (Tb), and/or cerium (Ce). In one or more embodiments, in this specification, the metal dopant may be referred to as “third metal”.

The hole injection doping layer P-HIL may include an organic dopant. The organic dopant may be, for example, a p-type or kind dopant. In one or more embodiments, the p-type or kind dopant may include at least one of 4-[[2,3-bis[cyano-(4-cyano-2,3,5,6-tetrafluorophenyl)methylidene]cyclopropylidene]-cyanomethyl]-2,3,5,6- tetrafluorobenzonitrile (hereinafter, referred to as NDP9), 1,4,5,8,9,11-hexaazatriphenylene-hexacarbonitrile (HAT-CN), 2,3,5,6-tetrafluoro-7,7,8,8-tetracyanoquinodimethane (F4-TCNQ), or tetracyanoquinodimethane (TCNQ). The organic dopant included in the hole injection doping layer P-HIL may include an organic material with a highest occupied molecular orbital (HOMO) level equal to or greater than about −6.0 eV and/or equal to or smaller than about −4.0 eV. According to one or more embodiments, the organic dopant included in hole injection doping layer P-HIL may have a doping concentration equal to or greater than about 0.5% and/or equal to or smaller than about 30%. The organic dopant included in the hole injection doping layer P-HIL may be substantially the same as or different from the organic dopant included in the p-type or kind charge generation layer P-CGL.

In one or more embodiments, referring to FIG. 3C, in the first, second, and third light emitting elements ED1, ED2, and ED3, one or more of the first, second, or third layer light emitting stacks may be provided as a common light emitting stack. As shown in FIG. 3C, the second layer light emitting stack SF2 (refer to FIG. 2A) may include the second light emitting stack ST-B, and the second light emitting stack ST-B provided as the second layer light emitting stack may be the common light emitting stack provided in all the first, second, and third light emitting elements ED1, ED2, and ED3. Each of the second electron transport layer ETL2, the second light emitting layer EML-B, and the second hole transport layer HTL2 included in the second light emitting stack ST-B corresponding to the second layer light emitting stack SF2 may be provided as the common layer that overlaps the first pixel area PXA-G, the second pixel area PXA-B, the third pixel area PXA-R, and the non-pixel area NPXA disposed between the first pixel area PXA-G, the second pixel area PXA-B, the third pixel area PXA-R. As the second layer light emitting stack SF2 (refer to FIG. 2A) is the second light emitting stack ST-B, the second layer light emitting stack SF2 (refer to FIG. 2A) of the first, second, and third light emitting elements ED1, ED2, and ED3 may have an integral shape. The bank BK may include a first bank BK1 overlapping the first layer light emitting stack SF1 (refer to FIG. 2A) and a second bank BK2 overlapping the third layer light emitting stack SF3 (refer to FIG. 2A) of the first, second, and third light emitting elements ED1, ED2, and ED3 when viewed in the first direction DR1, however, the present disclosure should not be limited thereto or thereby. According to one or more embodiments, one of the first layer light emitting stack SF1 or the third layer light emitting stack SF3 of the first, second, and third light emitting elements ED1, ED2, and ED3 may be a common light emitting stack.

As some of the first, second, and third layer light emitting stacks may be provided as the common light emitting stack in the first, second, and third light emitting elements ED1, ED2, and ED3, a portion of the charge generation layer disposed adjacent to the common light emitting stack may be provide as a common layer. As an example, as shown in FIG. 3C, the second light emitting stack ST-B provided as the second layer light emitting stack SF2 may be the common light emitting stack, and the n-type or kind charge generation layer disposed under the second light emitting stack ST-B provided as the second layer light emitting stack SF2 may be an n-type or kind common charge generation layer N-CGLC provided as the common layer. In one or more embodiments, the p-type or kind charge generation layer P-CGL disposed on the second light emitting stack ST-B corresponding to the second layer light emitting stack may be provided as a common layer.

The light emitting element included in the display device may have the inverted device structure in which the electron transport region is disposed under the light emitting layer and the hole transport region is disposed on the light emitting layer and may have the tandem structure in which each inverted device includes plural (e.g., multiple) light emitting stacks. In one or more embodiments, the charge generation layer included in the first light emitting element overlapping the first pixel area and the charge generation layer included in the second light emitting element overlapping the second pixel area may include different metal materials from each other. Accordingly, the light emitting characteristics of the light emitting element may be improved, a driving delay of the first light emitting element or the second light emitting element may be prevented or reduced, and thus, the display device may be driven at high speed and the display efficiency may be improved.

In one or more embodiments, among the light emitting elements included in the display device, the first light emitting element may include the first light emitting stacks and a first charge generation layer disposed between the first light emitting stacks, and the second light emitting element may include the second light emitting stacks and a second charge generation layer disposed between the second light emitting stacks. The n-type or kind first charge generation layer of the first charge generation layer may include the first metal, and the n-type or kind second charge generation layer of the second charge generation layer may include the second metal different from the first metal. According to the display device, the metal doping material for the n-type or kind charge generation layer of the first light emitting element and the metal doping material for the n-type or kind charge generation layer of the second light emitting element may be designed differently from each other, and thus, device characteristics, for example, a driving voltage of the first light emitting element and the second light emitting element, which emit different lights from each other, may be set to correspond to the light emitting range. Therefore, the display device including the first light emitting element and the second light emitting element may be driven at high speed, and the display efficiency may increase.

In one or more embodiments, as shown in FIGS. 3B and 3C, the display device may further include the electron injection doping layer between the first electrode and the first light emitting stacks and between the first electrode and the second light emitting stacks and the hole injection doping layer between the first light emitting stacks and the second electrode and between the second light emitting stacks and the second electrode, and thus, the charge injection characteristics from the electrode to the light emitting stack may be improved, and the luminous efficiency may be improved. In the case where the light emitting elements have the inverted device structure as in embodiments of the present disclosure, a difference in a lowest unoccupied molecular orbital (LUMO) level between the first electrode and the electron transport region may increase compared to a forward-biased direction light emitting element, and a difference in the highest occupied molecular orbital (HOMO) between the second electrode and the hole transport region may increase compared to a forward-biased direction light emitting element. However, according to embodiments of the present disclosure, as the light emitting element may include the electron injection doping layer and the hole injection doping layer, a charge injection barrier between the electrode and the light emitting stacks may be lowered. Thus, the charge injection characteristics of the light emitting element may be improved, and the luminous efficiency may be improved.

Table 1 shows the driving voltage characteristics of the light emitting element according to the metal doping material and the doping rate of the n-type or kind charge generation layer among the charge generation layers. In Table 1, the light emitting element including the first to third layer light emitting stacks as shown in FIGS. 2A and 3A are evaluated, and the driving voltage indicates a driving voltage at a current density of about 1.0 mA/cm2.

TABLE 1

| Metal doping material of n-type or kind | |
|---|---|
| charge generation layer and doping rate | Driving voltage (V) |
| Li 1% | 12.2 |
| Li 2% | 12.2 |
| Li 3% | 12.0 |
| Li 5% | 11.9 |
| Li 10% | 11.9 |
| Ca 5% | 13.9 |
| Yb 5% | 12.6 |

Referring to Table 1, it is observed that the driving voltage of the tandem light emitting element is changed as the metal doping material and the doping rate of the n-type or kind charge generation layer are varied. For example, it is observed that the driving voltage is reduced when the n-type or kind charge generation layer is doped with lithium having a relatively high electrical conductivity at a concentration of about 5% compared to when the n-type or kind charge generation layer is doped with ytterbium having a relatively low electrical conductivity at a concentration of about 5%. According to the results shown in Table 1, the n-type or kind charge generation layer included in the first light emitting element overlapping the first pixel area and the n-type or kind charge generation layer included in the second light emitting element overlapping the second pixel area in the display device may be designed to include different metal materials from each other, and thus, the device characteristics, such as the driving voltages of the first light emitting element and the second light emitting element that emit different lights from each other, may be set to correspond to the light emitting range. Accordingly, the display efficiency of the display device including the first light emitting element and the second light emitting element may be improved.

The display device and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the [device] may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present disclosure shall be determined according to the attached claims and their equivalents.

What is claimed is:

1. A display device comprising:
a base layer comprising a first pixel area configured to emit a first light therefrom and a second pixel area configured to emit a second light. different from the first light, therefrom;
a first electrode on the base layer;
a second electrode on the first electrode and facing the first electrode;
a plurality of first light emitting stacks between the first electrode and the second electrode and in the first pixel area;
a first charge generation layer between the first light emitting stacks;
a plurality of second light emitting stacks between the first electrode and the second electrode and in the second pixel area; and
a second charge generation layer between the second light emitting stacks, wherein the first charge generation layer comprises a first metal, the second charge generation layer comprises a second metal different from the first metal, and the second metal has a work function equal to or greater than about 1.7 eV and equal to or smaller than about 3.2 eV.

2. The display device of claim 1, wherein the first metal comprises ytterbium (Yb).

3. The display device of claim 1, wherein the second metal comprises at least one of lithium (Li), potassium (K), rubidium (Rb), cesium (Cs), barium (Ba), europium (Eu), sodium (Na), strontium (Sr), samarium (Sm), calcium (Ca), terbium (Tb), or cerium (Ce).

4. The display device of claim 1, further comprising:
an electron injection doping layer on the first electrode and under the first light emitting stacks and the second light emitting stacks; and
a hole injection doping layer on the first light emitting stacks and the second light emitting stacks and under the second electrode.

5. The display device of claim 4, wherein the electron injection doping layer comprises a third metal having a work function equal to or greater than about 1.7 eV and equal to or smaller than about 3.2 eV, and the hole injection doping layer comprises an organic material with a highest occupied molecular orbital (HOMO) level equal to or greater than about −6.0 eV and equal to or smaller than about −4.0 eV.

6. The display device of claim 4, wherein each of the electron injection doping layer and the hole injection doping layer entirely overlaps the first pixel area and the second pixel area.

7. The display device of claim 1, wherein at least a portion of the first light emitting stacks comprises a first light emitting layer configured to emit the first light, and at least a portion of the second light emitting stacks comprises a second light emitting layer configured to emit the second light.

8. The display device of claim 1, wherein the second charge generation layer does not overlap the first pixel area.

9. The display device of claim 1, further comprising:
a pixel definition layer on the base layer and provided with a plurality of openings defined therethrough to respectively correspond to the first pixel area and the second pixel area; and
a bank on the pixel definition layer and between at least a portion of the first light emitting stacks and at least a portion of the second light emitting stacks.

10. The display device of claim 1, wherein the first electrode is a reflective electrode, the second electrode is a transflective electrode or a transmissive electrode, and the first and second lights are configured to be emitted in a direction from the first electrode to the second direction.

11. The display device of claim 1, further comprising a circuit layer on the base layer and comprising a transistor electrically connected to the first electrode.

12. The display device of claim 11, wherein the transistor is an NMOS transistor.

13. The display device of claim 1, wherein each of the first light emitting stacks comprises:
a first electron transport layer adjacent to the first electrode;
a first light emitting layer on the first electron transport layer; and
a first hole transport layer spaced apart from the first electron transport layer with the first light emitting layer interposed therebetween and adjacent to the second electrode, and
wherein each of the second light emitting stacks comprises:
a second electron transport layer adjacent to the first electrode;
a second light emitting layer on the second electron transport layer; and
a second hole transport layer spaced apart from the second electron transport layer with the second light emitting layer interposed therebetween and adjacent to the second electrode.

14. The display device of claim 1, wherein the base layer comprises a third pixel area adjacent to the first pixel area and the second pixel area, and the first light emitting stacks overlap the third pixel area.

15. The display device of claim 14, wherein the base layer comprises a non-pixel area defined therein to be around each of the first pixel area, the second pixel area, and the third pixel area, and one or more of the first light emitting stacks overlap the non-pixel area.

16. The display device of claim 1, wherein the second metal has an electrical conductivity higher than an electrical conductivity of the first metal.

17. The display device of claim 1, wherein the first charge generation layer comprises an n-type first charge generation layer, the second charge generation layer comprises an n-type second charge generation layer, and the n-type first charge generation layer comprises the first metal, and the n-type second charge generation layer comprises the second metal.

18. A display device comprising:
a base layer comprising a first pixel area configured to emit a first light therefrom and a second pixel area configured to emit a second light, different from the first light, therefrom;
a first electrode on the base layer;
a second electrode on the first electrode and facing the first electrode;
a plurality of first light emitting stacks between the first electrode and the second electrode and in the first pixel area;
a first charge generation layer between the first light emitting stacks;
a plurality of second light emitting stacks between the first electrode and the second electrode and in the second pixel area; and
a second charge generation layer between the second light emitting stacks, wherein the first charge generation layer comprises ytterbium (Yb), and the second charge generation layer comprises at least one of lithium (Li), potassium (K), rubidium (Rb), cesium (Cs), barium (Ba), europium (Eu), sodium (Na), strontium (Sr), samarium (Sm), calcium (Ca), terbium (Tb), or cerium (Ce).

19. The display device of claim 18, wherein the first charge generation layer does not overlap the second pixel area, and the second charge generation layer does not overlap the first pixel area.

20. A display device comprising:
a base layer comprising a first pixel area configured to emit a first light therefrom and a second pixel area configured to emit a second light, different from the first light, therefrom;
a first electrode on the base layer;
a second electrode on the first electrode and facing the first electrode;
an electron injection doping layer on the first electrode;
a plurality of first light emitting stacks on the electron injection doping layer and in the first pixel area;
a first charge generation layer between the first light emitting stacks;
a plurality of second light emitting stacks on the electron injection doping layer and in the second pixel area;
a second charge generation layer between the second light emitting stacks; and
a hole injection doping layer on the plurality of first light emitting stacks and the plurality of second light emitting stacks and under the second electrode,
wherein the first charge generation layer comprises a first metal, and the second charge generation layer comprises a second metal different from the first metal.
